(19) United States
(12) Patent Application Publication
(10) Pub. No.: US 2024/0387648 A1
(43) Pub. Date: Nov. 21, 2024

(54) SEMICONDUCTOR DEVICE

(71) Applicant: Renesas Electronics Corporation, Tokyo (JP)

(72) Inventors: Katsumi EIKYU, Tokyo (JP); Atsushi SAKAI, Tokyo (JP); Tomoya NISHIMURA, Tokyo (JP)

(21) Appl. No.: 18/616,917

(22) Filed: Mar. 26, 2024

(30) Foreign Application Priority Data
May 16, 2023 (JP) 2023-080894

(51) Int. Cl. H01L 29/40; H01L 23/522; H01L 23/528; H01L 29/423

(52) U.S. Cl. CPC H01L 29/407; H01L 23/5226; H01L 23/528; H01L 29/4236

(57) ABSTRACT

Performance of a semiconductor device is improved. In a semiconductor substrate (SUB), a trench TR1 and a trench TR2 are formed so as to reach a predetermined depth from an upper surface (TS) of the semiconductor substrate (SUB). A field-plate electrode (FP) is formed at a lower portion of the trench TR1, and a gate-electrode GE1 is formed at an upper portion of the trench TR1. A gate electrode GE2 is formed inside the trench TR2. The depth of the trench TR1 is deeper than the depth of the trench TR2. The trench TR1 is surrounded by the trench TR2 in plan view.

### CROSS-REFERENCE TO RELATED APPLICATIONS

The disclosure of Japanese Patent Application No. 2023-080894 filed on May 16, 2023, including the specification, drawings and abstract is incorporated herein by reference in its entirety.

### BACKGROUND

The present disclosure relates to a semiconductor device, and more particularly, to a semiconductor device including a gate electrode and a field plate electrode inside a trench.

In a semiconductor device including a semiconductor device such as a power MOSFET (Metal Oxide Semiconductor Field Effect Transistor), a trench gate structure in which a gate electrode is embedded in a trench is applied.

For example, Patent Document 1 discloses a split gate structure in which a field plate electrode is formed at a lower portion of a trench and a gate electrode is formed at an upper portion of the trench as a type of trench gate structure. A source potential is supplied from the source electrode to the field plate electrode. By expanding the depletion layer from the field plate electrode to the drift region, the breakdown voltage around the trench can be improved. In addition, as the breakdown voltage is improved, the drift region can be increased in concentration, and the drift region can be reduced in resistance.

Non-Patent Document 1 discloses a technique in which a conventional trench gate structure (single gate structure) is arranged as an assist gate between trenches of a split gate structure, thereby increasing the density of gate electrodes in a cell area and reducing on-resistance. Such a power MOSFET is referred to as a split gate structure with an assist gate.

There are disclosed techniques listed below.
[Patent Document 1] Japanese Unexamined Patent Application Publication No. 2011-199109
[Non-Patent Document 1] W. Saito, et al., “Assist Gate MOSFETs for Improvement of On-Resistance and Turn-Off Loss Trade-Off”, IEEE ELECTRON DEVICE LETTERS, vol. 41, no. 7, pp. 1060-1062, July. 2020

### SUMMARY

In MOSFET of the split gate structure with the assist gate, in order to reduce the on-resistance, the withstand voltage must also be considered. That is, it is required not to destabilize the charge balance.

It is a primary purpose of the present application to optimize the planar layout of the split gate structure with an assist gate, thereby stabilizing the charge balance and improving the performance of a semiconductor device. Other objects and novel features will become apparent from the description of this specification and the accompanying drawings.

The typical ones of the embodiments disclosed in the present application will be briefly described as follows.

A semiconductor device according to one embodiment comprises: a semiconductor substrate of a first conductivity type having an upper surface and a lower surface; a first trench formed in the semiconductor substrate so as to reach a predetermined depth from the upper surface of the semiconductor substrate; a field plate electrode formed in a lower portion of the first trench inside the first trench and electrically isolated from the semiconductor substrate; a first gate electrode formed in an upper portion of the first trench inside the first trench and electrically isolated from the semiconductor substrate and the field plate electrode; a second trench formed in the semiconductor substrate so as to reach a predetermined depth from the upper surface of the semiconductor substrate; and a second gate electrode formed inside the second trench and electrically isolated from the semiconductor substrate.

A depth of the first trench is greater than a depth of the second trench. The first trench is surrounded by the second trench in plan view.

A semiconductor device according to one embodiment comprises: a semiconductor substrate of a first conductivity type having an upper surface and a lower surface; a first trench formed in the semiconductor substrate so as to reach a predetermined depth from the upper surface of the semiconductor substrate; a field plate electrode formed in a lower portion of the first trench inside the first trench and electrically isolated from the semiconductor substrate; a first gate electrode formed in an upper portion of the first trench inside the first trench and electrically isolated from the semiconductor substrate and the field plate electrode; a second trench formed in the semiconductor substrate so as to reach a predetermined depth from the upper surface of the semiconductor substrate; and a second gate electrode formed inside the second trench and electrically isolated from the semiconductor substrate. A depth of the first trench is greater than a depth of the second trench. In plan view, the first trench and the second trench each extend in a first direction and adjoin each other in a second direction intersecting the first direction.

According to one embodiment, the performance of a semiconductor device can be improved.

### BRIEF DESCRIPTION OF THE DRAWINGS

FIG. 1 is a plan view indicating a semiconductor device in the first embodiment.

FIG. 2 is a plan view indicating a semiconductor device in the first embodiment.

FIG. 3 is a main portion plan view indicating a semiconductor device in the first embodiment.

FIG. 4 is a main portion plan view indicating a semiconductor device in the first embodiment.

FIG. 5 is a cross-sectional view indicating a semiconductor device in the first embodiment.

FIG. 6 is a main portion plan view indicating a semiconductor device in the first embodiment.

FIG. 7 is an equivalent circuit diagram showing a semiconductor device in the first embodiment.

FIG. 8 is a cross-sectional view showing the manufacturing process of a semiconductor device in the first embodiment.

FIG. 9 is a cross-sectional view illustrating a manufacturing process following FIG. 8.

FIG. 10 is s cross-sectional view illustrating a manufacturing process following FIG. 9.

FIG. 11 is a cross-sectional view illustrating a manufacturing process following FIG. 10.

FIG. 12 is a cross-sectional view illustrating a manufacturing process following FIG. 11.

FIG. 13 is a cross-sectional view illustrating a manufacturing process following FIG. 12.

FIG. 14 is a cross-sectional view illustrating a manufacturing process following FIG. 13.

FIG. 15 is a cross-sectional view illustrating a manufacturing process following FIG. 14.

FIG. 16 is a cross-sectional view illustrating a manufacturing process following FIG. 15.

FIG. 17 is a cross-sectional view illustrating a manufacturing process following FIG. 16.

FIG. 18 is a cross-sectional view illustrating a manufacturing process following FIG. 17.

FIG. 19 is a cross-sectional view illustrating a manufacturing process following FIG. 18.

FIG. 20 is a cross-sectional view illustrating a manufacturing process following FIG. 19.

FIG. 21 is a cross-sectional view illustrating a manufacturing process following FIG. 20.

FIG. 22 is a main portion plan view indicating a semiconductor device in the first modified example.

FIG. 23 is a main portion plan view indicating a semiconductor device in the second embodiment.

FIG. 24 is a cross-sectional view indicating a semiconductor device in the second embodiment.

FIG. 25 is a main portion plan view indicating a semiconductor device in the second modified example.

FIG. 26 is a cross-sectional view indicating a semiconductor device in the second modified example.

FIG. 27 is a main portion plan view indicating a semiconductor device in the third embodiment.

FIG. 28 is a main portion plan view indicating a semiconductor device in the fourth embodiment.

FIG. 29 is a cross-sectional view indicating a semiconductor device in the fourth embodiment.

FIG. 30 is a main portion plan view indicating a semiconductor device in the fifth embodiment.

FIG. 31 is a cross-sectional view indicating a semiconductor device in the fifth embodiment.

FIG. 32 is a main portion plan view indicating a semiconductor device in the third modified example.

FIG. 33 is a cross-sectional view indicating a semiconductor device in the third modified example.

### DETAILED DESCRIPTION

In the following, embodiments will be explained in detail based on drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a depth direction, a height direction, or a thickness direction of a certain structure. In addition, the expression “plan view” used in the present application means that the plane formed by the X direction and the Y direction is a “plane” and the “plane” is viewed from the Z direction.

### First Embodiment

### <Structure of Semiconductor Device>

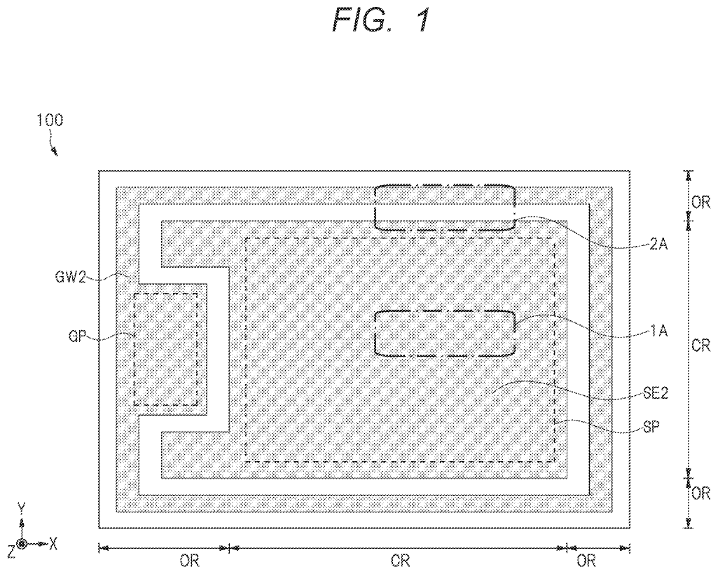

A semiconductor device 100 in the first embodiment will be described below with reference to FIGS. 1 to 7. The semiconductor device 100 includes a split-gate MOSFET with an assist gate as a semiconductor element. That is, in a semiconductor device 100, a MOSFET of the split gate structure including the gate electrode GE1 and the field plate electrode FP formed in the trench TR1 and a MOSFET of the single gate structure including the gate electrode GE2 formed in the trench TR2 are connected in parallel.

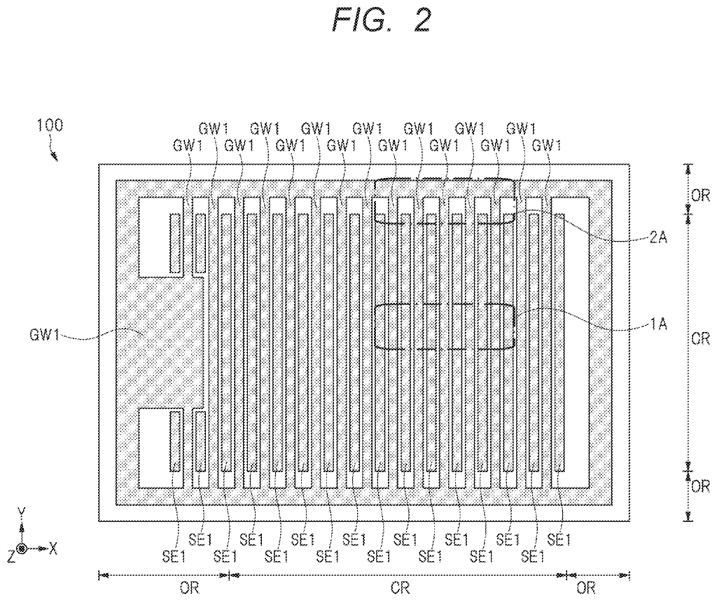

FIG. 1 and FIG. 2 are plan view of a semiconductor chip as a semiconductor device 100. FIG. 1 shows a top layer wiring construction. FIG. 2 shows a first layer wiring construction located between the top layer wiring and the semiconductor substrate SUB.

The semiconductor device 100 has a cell region CR and an outer peripheral region OR surrounding the cell region CR in plan view. In the cell region CR, main semiconducting elements such as a MOSFET are formed. More specifically, the cell region CR is a region in which the source region NS is formed and is a region that operates as a MOSFET. The outer peripheral region OR is mainly used for supplying a gate potential from the gate wiring GW2 to a MOSFET and functioning as a termination region etc.

As shown in FIG. 1, the majority of the cell area CR is covered with the source electrode SE2. In plan view, the gate wiring GW2 surrounds the source electrode SE2. Although not illustrated here, the source electrode SE2 and the gate wiring GW2 are covered with a protective film such as a polyimide film. An opening is provided in a part of the protective film, and the source electrode SE2 and the gate wiring GW2 exposed in the opening become the source pad SP and the gate pad GP. An external connecting member is connected to the source pad SP and the gate pad GP, so that a semiconductor device 100 is electrically connected to another semiconductor chip, a lead frame, a wiring substrate, or the like. The external connection member is, for example, a wire made of aluminum, gold, or copper, or a clip made of a copper plate.

As shown in FIG. 2, in the cell area CR, a plurality of internal wirings SE1 for a source and a plurality of internal wirings GW1 for a gate extending in the Y-direction are formed. The inner wiring GW1 is also formed in the outer peripheral region OR so as to be located below the gate wiring GW2. The plurality of inner wirings GW1 in the cell region CR are integrated with the inner wiring GW1 in the outer peripheral region OR.

As will be described later, the inner wiring SE1 is electrically connected to the source electrode SE2 via hole CH4 (via V1) formed in the interlayer insulating film IL2. The inner wiring GW1 is electrically connected to the gate wiring GW2 through a hole (via) equivalent to the hole CH4 (via V1).

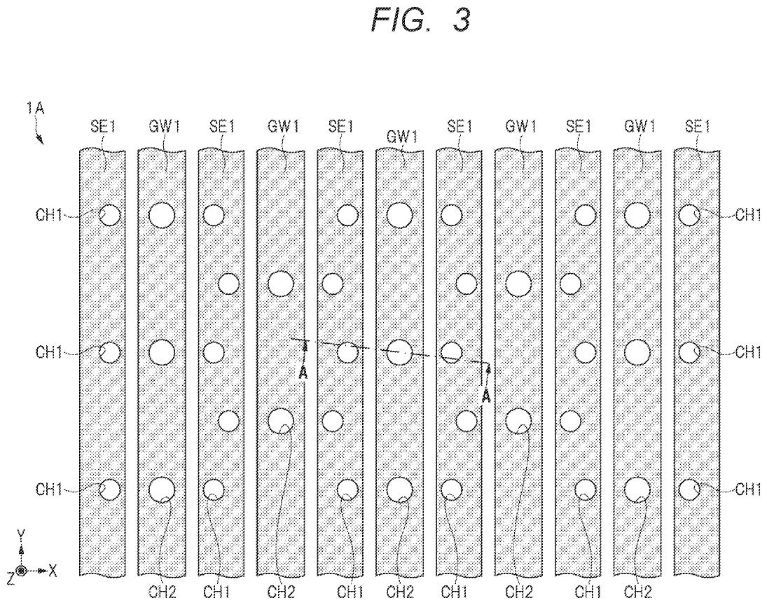

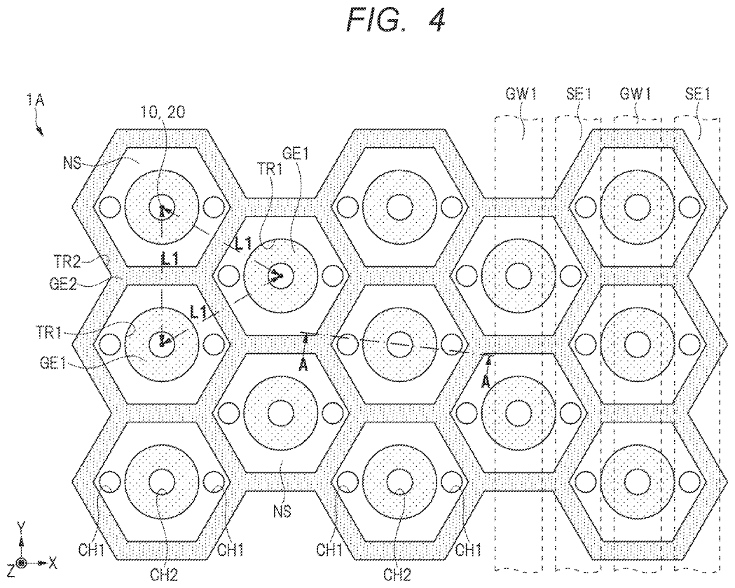

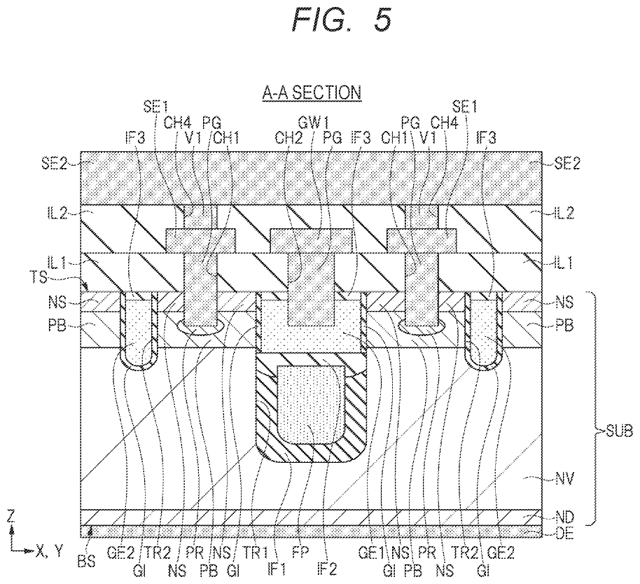

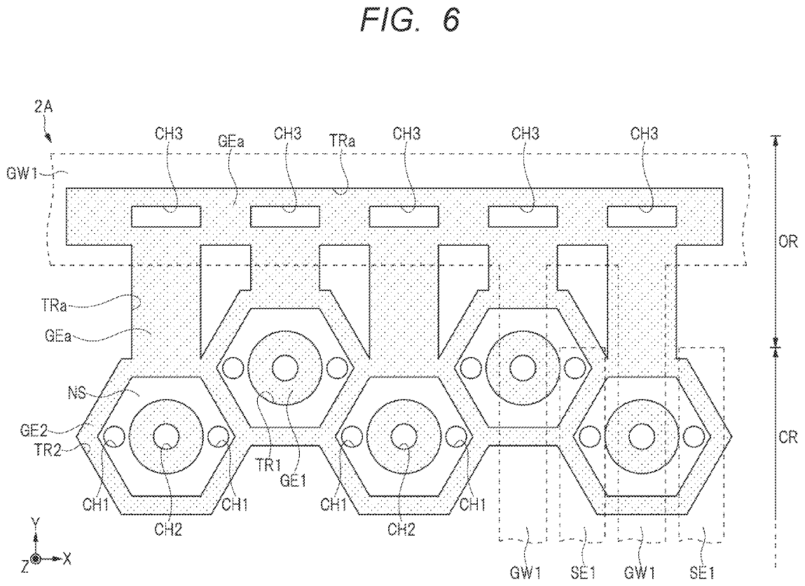

FIG. 3 and FIG. 4 are enlarged main portion plan view of the region 1A shown in FIGS. 1 and 2. FIG. 6 is an enlarged main portion plan view of the region 2A shown in FIGS. 1 and 2. FIG. 3 shows wiring construction of the first layer of FIG. 2. FIG. 4 and FIG. 6 mainly show planar patterns of the trenches TR1, TR2 and the gate electrodes GE1, GE2 formed in the semiconductor substrate SUB. FIG. 5 is a cross-sectional view along A-A lines shown in FIGS. 3 and 4.

Note that in plan view of FIG. 3, the holes CH1, CH2 are actually illustrated in order to make the positional relation with FIG. 4 easy to understand, although the holes CH1, CH2 are covered with the inner wiring SE1 and the inner wiring GW1 and are not visually recognized. Further, in FIGS. 4 and 6, in order to make the positional relation between the inner wiring SE1 and the inner wiring GW1 easy to understand, portions of these portions are shown by broken lines.

As shown in FIGS. 3 and 4, in the cell area CR, the plurality of inner wirings SE1 and the plurality of inner wirings GW1 are each formed in a stripe-like shape, extend in the Y direction, and adjoin each other in the X direction. The inner wiring SE1 is electrically connected to the source-region NS via the hole CH1. The inner wiring GW1 is electrically connected to the gate electrode GE1 via the hole CH2.

In FIG. 4, the planar shapes of the hole CH1 and the hole CH2 are shown as a circular shape, but the planar shapes of the hole CH1 and the hole CH2 may be other shapes such as a square shape.

As shown in FIG. 4, the trench TR2 has a honeycomb structure in plan view. That is, the trench TR2 has a configuration in which a plurality of regular hexagons are connected to each other. A gate electrode GE2 is formed inside the trench TR2. The planar shape of the trench TR1 is a circular shape. A gate electrode GE1 is formed inside the trench TR1. The trench TR1 is surrounded by the trench TR2 in plan view. The source region NS is formed between the trench TR1 and the trench TR2.

In the first embodiment, one trench TR1 is formed in one regular hexagon of the honeycomb structure of the trench TR2. In addition, the center portion 10 of the trench TR1 in plan view corresponds to (matches) the center of gravity (centroid) 20 of one regular hexagon of the honeycomb structure. Therefore, when the center portions 10 of the three nearest trenches TR1 are connected by a straight line, an equilateral triangle is formed. As shown in FIG. 4, the length L1 of the respective sides of the equilateral triangle are equal.

A field plate electrode FP, which will be described later, is formed at a lower portion of the gate electrode GE1 in the trench TR1. With the above-described equilateral triangle, the depletion layer extending from the field plate electrode FP easily spreads evenly in the cell region CR, and thus the breakdown voltage is easily secured.

Note that the center of gravity 20 indicates a center of gravity of a polygon and may be a center of gravity of a regular quadrangle as in the first modified example described later.

A cross-sectional configuration of a semiconductor device 100 will be described below with reference to FIG. 5.

As shown in FIG. 5, a semiconductor device 100 comprises an n-type semiconductor substrate SUB having an upper surface TS and a bottom surface BS. The semiconductor substrate SUB is made of n-type silicon. The semiconductor substrate SUB has a low concentration n-type drift region NV. In the first embodiment, the n-type semiconductor substrate SUB itself constitutes the drift-region NV. The semiconductor substrate SUB may be a laminate of an n-type silicon substrate and an n-type semiconductor layer grown on the silicon substrate while introducing phosphorus (P) by an epitaxial growth method. In that case, the low-concentration n-type semiconductor layer constitutes the drift region NV, and the high-concentration n-type silicon substrate constitutes the drain region ND.

As shown in FIG. 5, in the semiconductor substrate SUB, an n-type drain-region ND is formed closer to the lower surface BS of the semiconductor substrate SUB than to the upper surface TS of the semiconductor substrate. The drain region ND has a higher impurity concentration than the drift region NV. A drain-electrode DE is formed below the lower surface BS of the semiconductor substrate SUB. The drain electrode DE consist of, e.g., a single layer of metallic membrane, such as aluminum membrane, titanium membrane, nickel membrane, gold membrane or silver membrane, or of laminated membranes with these metallic membranes laminated accordingly. The drain region ND and the drain electrode DE are formed over the cell region CR and the outer peripheral region OR. The drain potential is supplied to the semiconductor substrate SUB (drain region ND, drift region NV) from the drain electrode DE.

The semiconductor substrate SUB is formed with a trench TR1 that reaches a predetermined depth from the upper surface TS of the semiconductor substrate SUB. The depth of the trench TR1 is, for example, 5 μm (micrometers) or more and 7 μm (micrometers) or less. Inside the trench TR1, a field plate electrode FP is formed at a lower portion of the trench TR1 via an insulating film IF1. Further, inside the trench TR1, a gate electrode GE1 is formed at an upper portion of the trench TR1 via a gate insulating film GI. Each of the field plate electrode FP and the gate electrode GE1 is formed of, for example, an n-type doped polycrystalline silicon film.

The position of the upper surface of the insulating film IF1 is lower than the position of the upper surface of the field plate FP. An insulating film IF2 is formed so as to cover the field plate electrode FP exposed from the insulating film IF1. The gate insulating film GI is formed inside the trench TR1 on the insulating film IF2.

The insulating film IF1 is formed between the semiconductor substrate SUB and the field plate FP. The insulating film IF2 is formed between the gate electrode GE1 and the field plate electrode FP. The gate insulating film GI is formed between the semiconductor substrate SUB and the gate electrode GE1. With these films, the semiconductor substrate SUB, the gate electrode GE1, and the field plate electrode FP are electrically insulated from each other. An insulating film IF3 is formed on the gate electrode GE1.

The insulating film IF1, the insulating film IF2, the insulating film IF3, and the gate insulating film GI are made of, for example, a silicon-oxide film. The thickness of the insulating film IF1 is larger than the thickness of the gate insulating film GI. Inside the trench TR1, the thickness of the insulating film IF1 is, for example, 400 nm or more and 600 nm or less. In the trench TR1, the thickness of the gate insulating film GI is, for example, equal to or greater than 50 nm and equal to or less than 70 nm. These thicknesses are thicknesses in the X direction.

The semiconductor substrate SUB is formed with a trench TR2 that reaches a predetermined depth from the upper surface TS of the semiconductor substrate SUB. As shown in FIG. 5, the depth of the trench TR2 is shallower than the depth of the trench TR1 and is, for example, 2 μm (micrometers) or more and 3 μm (micrometers) or less. A gate electrode GE2 is formed inside the trench TR2 via the gate insulating film GI. The semiconductor substrate SUB and the gate electrode GE2 are electrically insulated from each other by the gate insulating film GI. The gate electrode GE2 is formed of, for example, an n-type doped polycrystalline silicon film. An insulating film IF3 is formed on the gate electrode GE2.

In the semiconductor substrate SUB, a p-type body area PB is formed closer to the upper surface TS of the semiconductor substrate SUB than to the lower surface BS of the semiconductor substrate SUB. As shown in FIG. 5, the depth of the body region PB from the upper surface TS of the semiconductor substrate SUB is shallower than the depth of each of the trench TR1 and the trench TR2. In the body region PB, an n-type source region NS is formed. The source region NS has a higher impurity concentration than the drift region NV.

An interlayer insulating film IL1 is formed on the upper surface TS of the semiconductor substrate SUB so as to cover the trench TR1 and the trench TR2. The interlayer insulating film IL1 is formed of, for example, a silicon oxide film. The thickness of the interlayer insulating film IL1 is, for example, 500 nm or more and 900 nm or less.

A hole CH1 and a hole CH2 are formed in the interlayer insulating film IL1. The hole CH1 reaches the source-region NS and the body-region PB. The hole CH2 reaches the gate electrode GE2. At the bottom of the hole CH1, a high concentration diffusion region PR is formed in the body region PB. The high-concentration diffusion region PR is mainly formed in order to reduce the contact-resistance with the plug PG and has a higher impurity concentration than the body region PB.

A plug PG is formed inside each of the hole CH1 and the hole CH2. The plug PG includes, for example, a first barrier metal film and a first conductive film formed on the first barrier metal film. The first barrier metal film is formed of, for example, a laminated film of a titanium film and a titanium nitride film. The first conductive film is, for example, a tungsten film.

An inner wiring SE1 and an inner wiring GW1 are formed on the interlayer insulating film IL1. The inner wiring SE1 is provided at a position overlapping the hole CH1 in plan view and is electrically connected to the source-region NS, the body-region PB, and the high-concentration diffusion-region PR via the hole CH1 (plug PG). The inner wiring GW1 is provided at a position overlapping the hole CH2 in plan view and is electrically connected to the gate electrode GE1 via the hole CH2 (plug PG).

The inner wiring SE1 and the inner wiring GW1 include, for example, a second barrier metal film and a second conductive film formed on the second barrier metal film. The second barrier metal film is, for example, a titanium tungsten film or a titanium nitride film. The second conductive film is, for example, an aluminum alloy film to which copper or silicon is added, or a tungsten film. The thickness of each of the inner wiring SE1 and the inner wiring GW1 is, for example, greater than or equal to 100 nm and less than or equal to 200 nm.

An interlayer insulating film IL2 is formed on the interlayer insulating film IL1 so as to cover the inner wiring SE1 and the inner wiring GW1. The interlayer insulating film IL2 is formed of, for example, a silicon oxide film. The thickness of the interlayer insulating film IL2 is, for example, 500 nm or more and 900 nm or less.

A hole CH4 is formed in the interlayer insulating film IL2. The hole CH4 reaches the internal wiring SE1. A via V1 is formed inside the hole CH4. The via V1 includes, for example, a third barrier metal film and a third conductive film formed on the third barrier metal film. The third barrier metal film is formed of, for example, a laminated film of a titanium film and a titanium nitride film. The third conductive film is, for example, a tungsten film.

A source electrode SE2 is formed on the interlayer insulating film IL2. The source electrode SE2 is electrically connected to the inner wiring SE1 via the hole CH4 (via V1). Therefore, the source potential is supplied from the source electrode SE2 to the source region NS, the body region PB, and the high-concentration diffusion region PR.

As shown in FIG. 6, in the semiconductor substrate SUB of the outer peripheral region OR, an lead-out trench TRa that reaches a predetermined depth from the upper surface TS of the semiconductor substrate SUB is formed. The depth of the lead-out trench TRa is the same as the depth of the trench TR2 because the lead-out trench TRa is formed in the same manufacturing process as the trench TR2. The trench TR2 and the lead-out trench TRa are in communication. A lead-out portion GEa integrated with the gate electrode GE2 is formed inside the lead-out trench TRa.

A hole CH3 reaching the lead-out portion GEa is formed in the interlayer insulating film IL1 of the outer peripheral region OR. A plug PG is also formed inside the hole CH3. The inner wiring GW1 is also formed in the outer peripheral region OR. The inner wiring GW1 of the outer peripheral region OR is provided at a position overlapping the hole CH3 in plan view and is electrically connected to the lead-out portion GEa via hole CH3 (plug PG).

Although not illustrated here, a gate wiring GW2 is formed on the interlayer insulating film IL2 in the outer peripheral region OR. In addition, a hole CH4 reaching the inner wiring GW1 is formed in the interlayer insulating film IL2 in the outer peripheral region OR, and a via V1 is also formed in the hole CH4. The gate wiring GW2 is electrically connected to the inner wiring GW1 via hole CH4 (via V1). Therefore, the gate potential is supplied from the gate wiring GW2 to the gate electrode GE1 and the gate electrode GE2.

The source electrode SE2 and the gate wiring GW2 include, for example, a fourth barrier metal film and a fourth conductive film formed on the fourth barrier metal film. The fourth barrier metal film is, for example, a titanium tungsten film. The fourth conductive film is, for example, an aluminum alloy film to which copper or silicon is added. The thickness of each of the source electrode SE2 and the gate electrode wiring GW2 is larger than the thickness of each of the inner wiring SE1 and the inner wiring GW1, and is, for example, 2 μm (micrometers) or more and 3 μm (micrometers) or less.

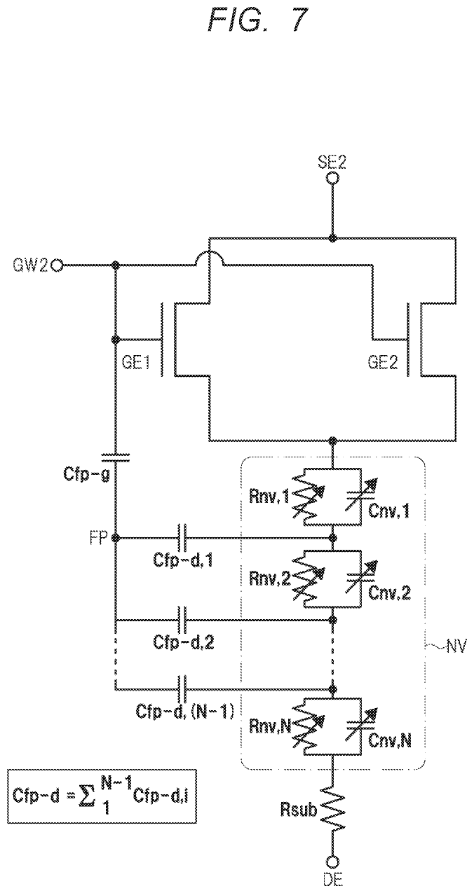

FIG. 7 is an equivalent schematic diagram of a MOSFET of a split gate structure with an assist gate in the first embodiment. A split gate structure MOSFET including a gate electrode GE1 and a field plate electrode FP, and a single gate structure MOSFET including a gate electrode GE2, are connected in parallel. The field plate electrode FP is not electrically connected to any of the gate wiring GW2, the source electrode SE2, and the drain electrode DE, and is electrically floating.

Note that the capacitance Cfp-g shown in FIG. 7 is a capacitance between the gate electrode GE1 and the field plate electrode FP. The capacitance Cfp-d is a capacitance between the field plate electrode FP and the drain electrode DE. The resistance Rsub is a resistance component of the drain region ND. The drift-region NV constitutes a distributed-constant bias-dependent variable resistive Rnv,N/variable capacitance Cnv,N (N is an integer). Therefore, the potential applied to the field plate electrode FP varies at these intermediate potentials depending on the gate-potential and the drain-potential.

As described above, according to the first embodiment, the body region PB in contact with the side surface of the trench TR1 can be utilized as the channel region of MOSFET of the split gate structure, and the body region PB in contact with the side surface of the trench TR2 can be utilized as the channel region of MOSFET of the single gate structure. By adopting a configuration in which the trench TR2 surrounds the trench TR1 in plan view, the density of the gate electrode GE2 in the cell region CR increases, and the density of the current flowing through the entire cell region CR increases. Therefore, the on-resistance can be reduced.

The trench TR2 forms a honeycomb structure in plan view, and the center portion 10 of the trench TR1 corresponds to (matches) the center of gravity 20 of one regular hexagon of the honeycomb structures. Therefore, an equilateral triangle is formed by the center portions 10 of the three nearest trenches TR1. As a result, the depletion layer extending from the field plate electrode FP easily spreads evenly in the cell area CR, and thus the breakdown voltage is easily secured.

Thus, the first embodiment does not destabilize the charge balance. In other words, according to the first embodiment, since the charge balance is stabilized, it is possible to achieve both reduce of the on-resistance and securing of the withstand voltage, and consequently, it is possible to improve the result of a semiconductor device 100.

### <Manufacturing Method of Semiconductor Device>

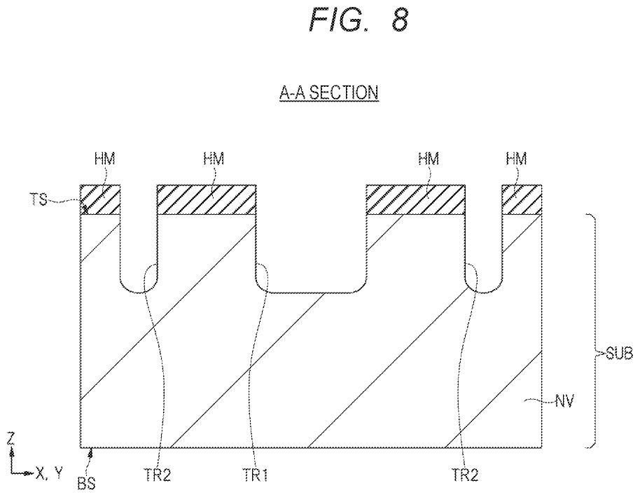

The respective manufacturing steps included in the manufacturing method of a semiconductor device 100 will be described below with reference to FIG. 8 to FIG. 21.

As shown in FIG. 8, first, an n-type semiconductor substrate SUB having an upper surface TS and a lower surface BS is prepared. As mentioned above, semiconductor substrate SUB may be a stack of n-type silicon substrate and an n-type semiconducting layer formed on the silicon substrate by epitaxial growth.

Next, a trench TR1 and a trench TR2 are formed in the semiconductor substrate SUB so as to reach a predetermined depth from the upper surface TS of the semiconductor substrate SUB. For this purpose, first, an insulating film such as a silicon oxide film or a silicon nitride film is formed on the upper surface TS of the semiconductor substrate SUB by, for example, CVD (Chemical Vapor Deposition). Next, the insulating film is patterned by a photolithography technique and an anisotropic etch process to selectively form a hard mask HM on the upper surface TS of the semiconductor substrate SUB. Next, an anisotropic etch process is performed using the hard mask HM as a mask to form a trench TR1 and a trench TR2 in the semiconductor substrate SUB exposed from the hard mask HM. Through these steps, a lead-out trench TRa is also formed.

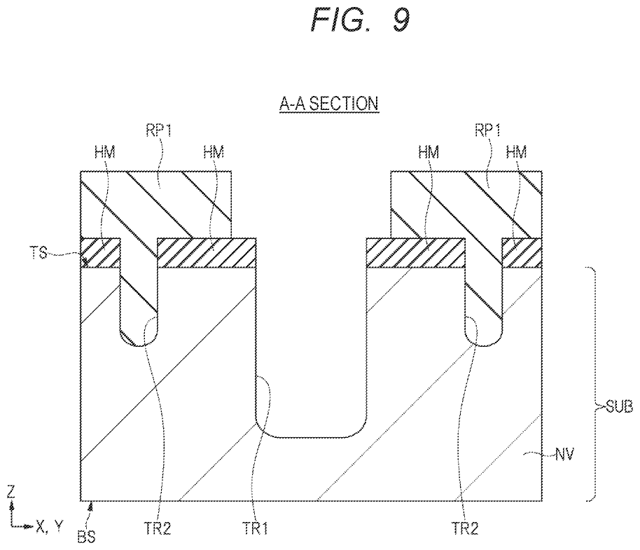

As shown in FIG. 9, the depth of the trench TR1 is selectively made deeper so that the depth of the trench TR1 is deeper than the depth of the trench TR2.

First, a resist pattern RP1 having a pattern covering the trench TR2 and opening the trench TR1 is formed on the hard mask HM. Next, an anisotropic etch process is performed using the resist pattern RP1 and the hard mask HM as masks. Since the upper surface TS of the semiconductor substrate SUB exposed from the resist pattern RP1 is covered with the hard mask HM, only the inside of the trench TR1 is etched. This selectively increases the depth of the trench TR1.

Next, the resist pattern RP1 is removed by ashing. The hard mask HM is then removed by an isotropic etch process using, for example, hydrofluoric acid or phosphoric acid-containing solutions.

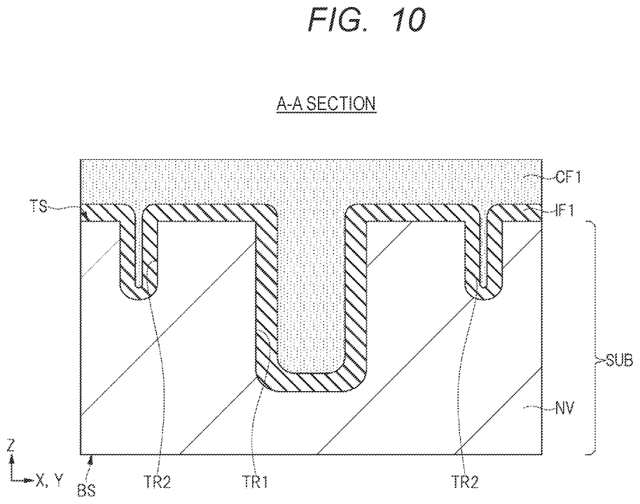

As shown in FIG. 10, an insulating film IF1 and a conductive film CF1 are formed inside the trench TR1 and inside the trench TR2.

First, an insulating film IF1 is formed on the upper surface TS of the semiconductor substrate SUB, inside the trench TR1, and inside the trench TR2 by, for example, thermal oxidation treatment. The insulating film IF1 may be a stacked film of a first silicon oxide film formed by thermal oxidation treatment and a second silicon oxide film formed by CVD on the first silicon oxide film.

Next, a conductive film CF1 is formed on the insulating film IF1 by, for example, a CVD method so as to fill the inside of the trench TR1 and the inside of the trench TR2. The conductive film CF1 is, for example, an n-type polycrystalline silicon film. In order to satisfactorily fill the conductive film CF1, the conductive film CF1 may be formed a plurality of times (for example, two times as forming the first polycrystalline silicon film and forming the second polycrystalline silicon film).

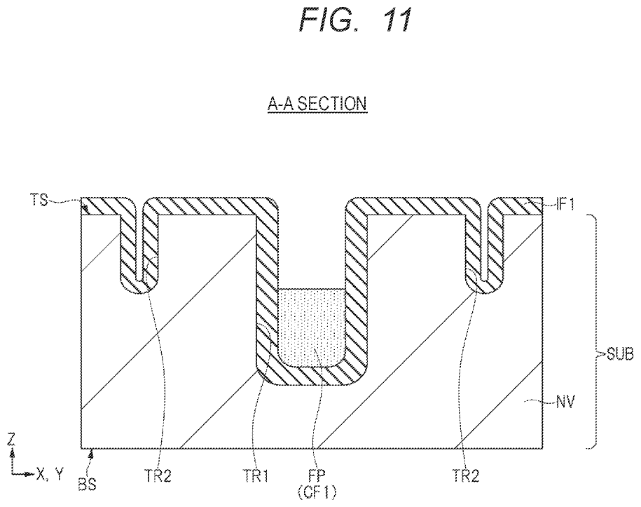

As shown in FIG. 11, a field plate electrode FP is formed inside the trench TR1.

First, the conductive film CF1 located on the upper surface TS of the semiconductor substrate SUB is removed by a polishing process using, for example, CMP (Chemical Mechanical Polishing method. Next, an anisotropic etch process is performed on the conductive film CF1 to remove the conductive film CF1 located inside the trench TR2 and a portion of the conductive film CF1 located inside the trench TR1. As a result, the conductive film CF1 left in the trench TR1 is formed as the field plate electrode FP.

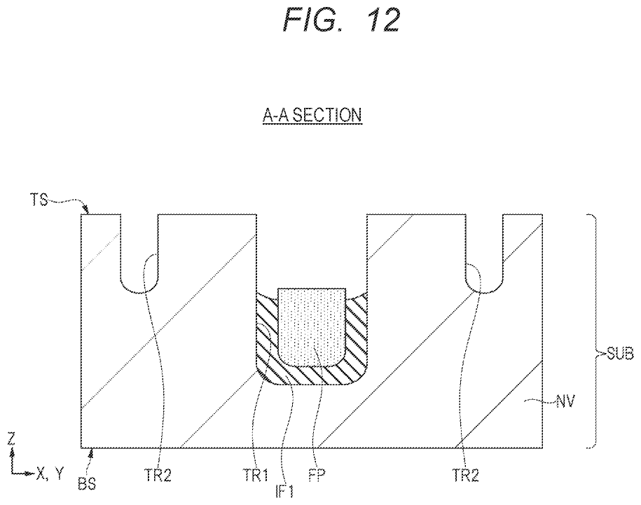

As shown in FIG. 12, the insulating film IF1 is subjected to an isotropic etch process using solutions containing hydrofluoric acid. Thus, the insulating film IF1 located on the upper surface TS of the semiconductor substrate SUB and the insulating film IF1 located inside the trench TR2 are removed. At the same time, the insulating film IF1 inside the trench TR1 is retracted toward the bottom of the trench IF1 so that the position of the upper surface of the insulating film IF1 located inside the trench TR1 is lower than the position of the upper surface of the field plate electrode FP.

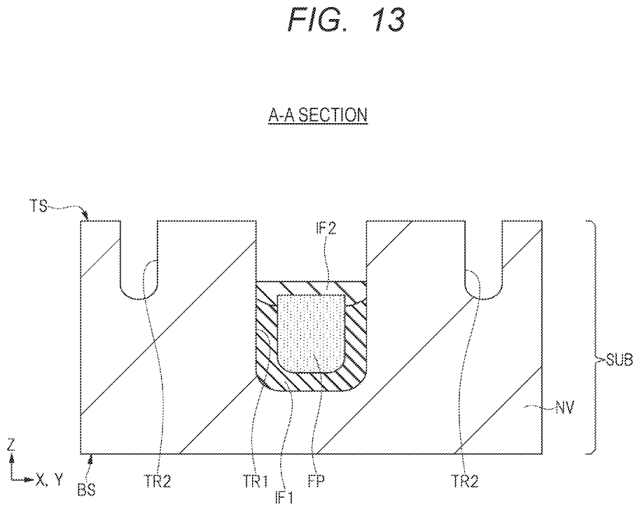

As shown in FIG. 13, an insulating film IF2 is selectively formed in the trench TR1 so as to cover the field plate electrode FP exposed from the insulating film IF1.

First, an insulating film IF2 is formed on the upper surface TS of the semiconductor substrate SUB, inside the trench TR1, and inside the trench TR2 by, for example, a CVD method. Next, an anisotropic etch process is performed on the insulating film IF2 to remove the insulating film IF2 located on the semiconductor substrate SUB's upper surface TS and the insulating film IF2 located inside the trench TR2. At the same time, the insulating film IF2 located inside the trench TR1 is retracted toward the bottom of the trench TR1. As a result, the field plate electrode FP is covered with the insulating film IF2 left in the trench TR1.

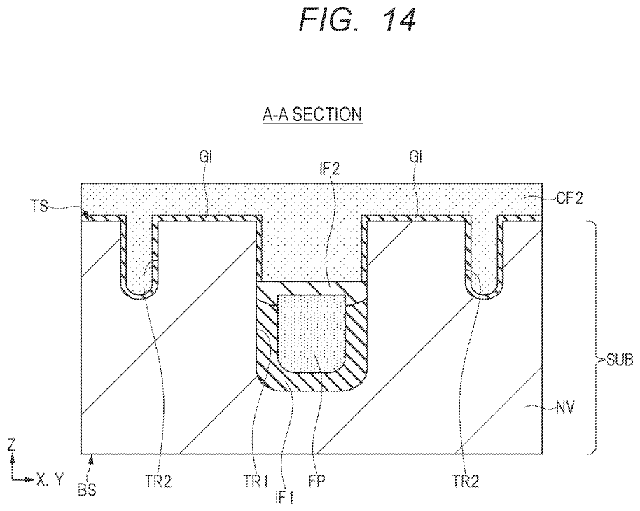

As shown in FIG. 14, a gate insulating film GI and a conductive film CF2 are formed inside the trench TR1 and inside the trench TR2.

First, a gate insulating film GI is formed on the upper surface TS of the semiconductor substrate SUB, inside the trench TR1 located on the insulating film IF2, and inside the trench TR2 by the thermal oxidization treatment. A gate insulating film GI is also formed inside the lead-out trench TRa. Next, a conductive film CF2 is formed on the gate insulating film GI and on the insulating film IF2 by, for example, a CVD method so as to fill the inside of the trench TR1. The conductive film CF2 is, for example, an n-type polycrystalline silicon film.

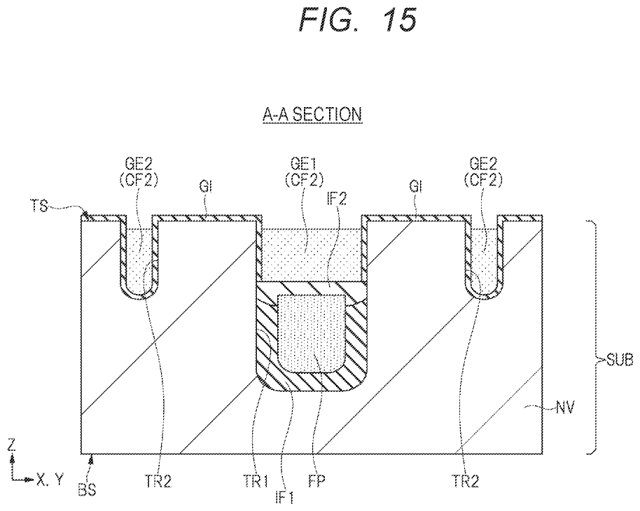

As shown in FIG. 15, a gate electrode GE1 is formed inside the trench TR1, and a gate electrode GE2 is formed inside the trench TR2.

First, a polishing treatment using a CMP method is performed on the conductive film CF2 by, for example, a polishing treatment using a CMP method. As a result, the thickness of the conductive film CF2 is reduced, and the upper surface of the conductive film CF2 is planarized.

Next, an anisotropic etch process is performed on the conductive film CF2 to remove the conductive film CF2 located on the semiconductor substrate SUB's upper surface TS. Accordingly, the conductive film CF2 left in the trench TR1 on the field plate electrode FP is formed as the gate electrode GE1. At the same time, the conductive film CF2 left in the trench TR2 is formed as the gate electrode GE2. The lead-out portion GEa is also formed inside the lead-out trench TRa from the conductive film CF2.

In order to completely remove the conductive film CF2 outside the trench TR1 and outside the trench TR2, the anisotropic etching process is performed by overetching. The position of the upper surface of each of the gate electrode GE1 and the gate electrode GE2 is slightly lower than the position of the upper surface TS of the semiconductor substrate SUB.

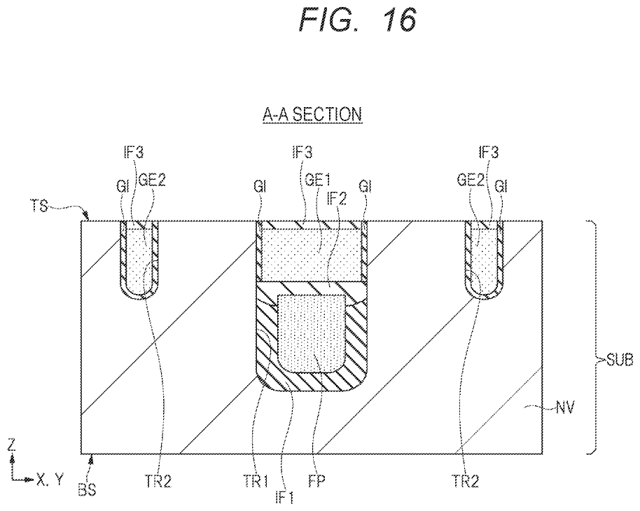

As shown in FIG. 16, an insulating film IF3 is formed on the upper surface of each of the gate electrode GE1 and the gate electrode GE2.

First, an insulating film IF3 is formed on the upper surface TS of the semiconductor substrate SUB by, for example, a CVD method so as to cover the upper surface of each of the gate electrode GE1 and the gate electrode GE2. Next, the insulating film IF3 is subjected to an anisotropic etch process. As a result, the insulating films IF3 and the gate insulating film GI on the upper surface TS of the semiconductor substrate SUB are removed, and the insulating film IF3 is left on each of the upper surfaces of the gate electrode GE1 and the gate electrode GE2.

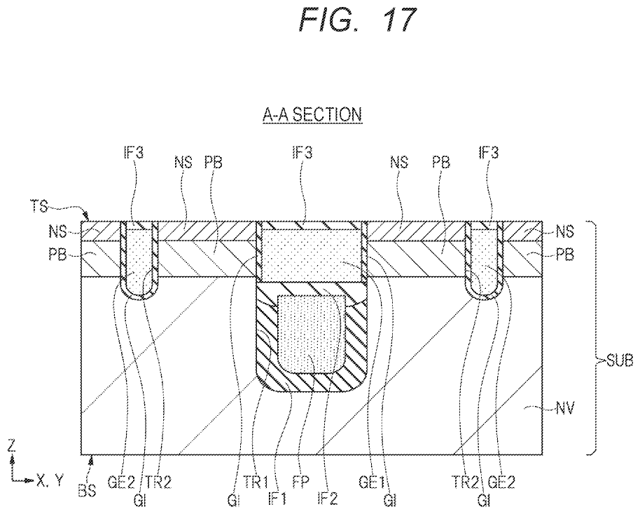

As shown in FIG. 17, a body region PB and a source region NS are formed in the semiconductor substrate SUB.

First, a p-type body area PB is selectively formed in the semiconductor substrate SUB by introducing, for example, boron (B) by photolithography and ion-implantation. The body area PB is formed to be shallower than the depth of each of the trench TR1 and the trench TR2.

Next, an n-type source region NS is selectively formed in the body region PB of the cell region CR by introducing, for example, arsenic (As) by photolithography and ion-implantation. Thereafter, the semiconductor substrate SUB is subjected to a heat treatment to activate impurities contained in the source region NS and the body region PB.

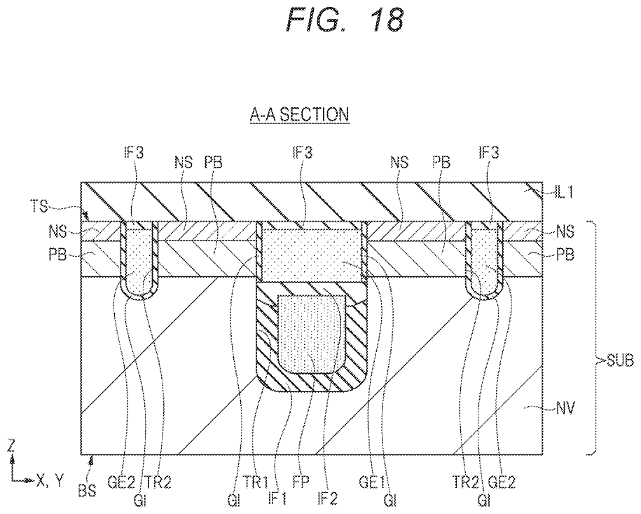

As shown in FIG. 18, the interlayer insulating film IL1 is formed on the upper surface TS of the semiconductor substrate SUB by, for example, a CVD method so as to cover the trench TR1 and the trench TR2.

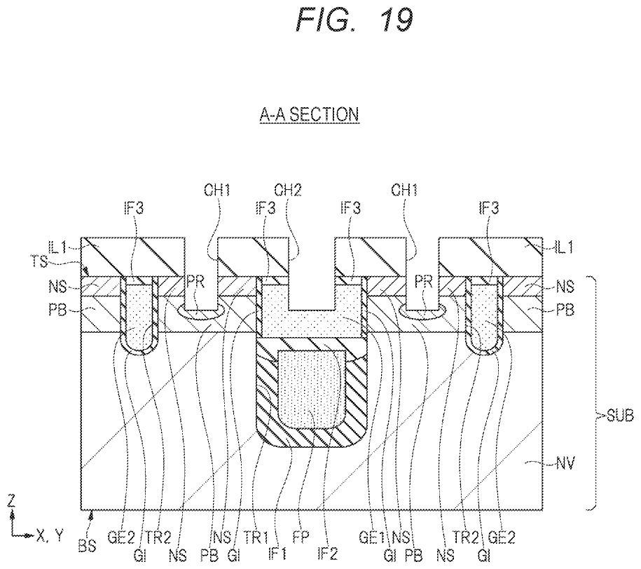

As shown in FIG. 19, a hole CH1, a hole CH2, and a high concentration diffusion region PR are formed.

First, on the interlayer insulating film IL1, a resist pattern having a pattern for opening the semiconductor substrate SUB in which the source-region NS is formed is formed. Next, an anisotropic etch process is performed using the resist pattern as a mask to form a hole CH1 penetrating through the interlayer insulating film IL1 and the source region NS and reaching the inside of the body region PB. Next, a p-type high concentration diffusion region PR is formed by introducing, for example, boron (B) into the body region PB at the bottom of the hole CH1 by the ion-implantation method. Thereafter, such resist pattern is removed by an ashing process.

Next, a resist pattern having a pattern opening over the gate electrode GE1 is formed on the interlayer insulating film IL1. Next, an anisotropic etch process is performed using the resist pattern as a mask to form a hole CH2 that penetrates the interlayer insulating film IL1 and the insulating film IF3 and reaches the gate electrode GE1. Although not shown here, in the step of forming the hole CH2, the hole CH3 shown in FIG. 6 is also formed. The hole CH3 penetrates through the interlayer insulating film IL1 and the insulating film IF3 and reaches the lead-out portion GEa. Thereafter, RP1 to Such resist pattern is removed by an ashing process.

The order in which the hole CH1 is formed and the order in which the hole CH2 and the hole CH3 are formed may be any order in which any of them is formed first.

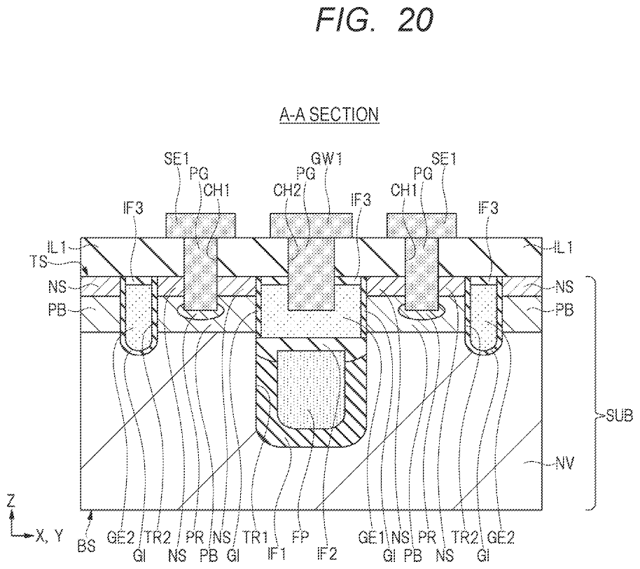

As shown in FIG. 20, a plug PG is formed inside each of the hole CH1 and the hole CH2, and an inner wiring SE1 and an inner wiring GW1 are formed on the interlayer insulating film IL1.

First, a first barrier metal film is formed inside the hole CH1, inside the hole CH2, and on the interlayer insulating film IL1 by a sputtering method or a CVD method. The first barrier metal film is formed of, for example, a laminated film of a titanium nitride film and a titanium film. Next, a first conductive film is formed on the first barrier metal film by CVD method. The first conductive film is formed of, for example, a tungsten film.

Next, the first barrier metal film and the first conductive film formed outside the hole CH1 and outside the hole CH2 are removed by polishing using CMP method or anisotropic etching. As a result, the plug PG including the first barrier metal film and the first conductive film is formed so as to fill the inside of the hole CH1 and the inside of the hole CH2. Through these steps, a plug PG is also formed inside the hole CH3.

Next, a second barrier metal film is formed on the interlayer insulating film IL1 by sputtering. The second barrier metal film is formed of, for example, a titanium tungsten film or a titanium nitride film. Next, a second conductive film is formed on the second barrier metal film by sputtering. The second conductive film is, for example, an aluminum alloy film to which copper or silicon is added, or a tungsten film. Next, the second barrier metal film and the second conductive film are patterned to form an inner wiring SE1 and an inner wiring GW1.

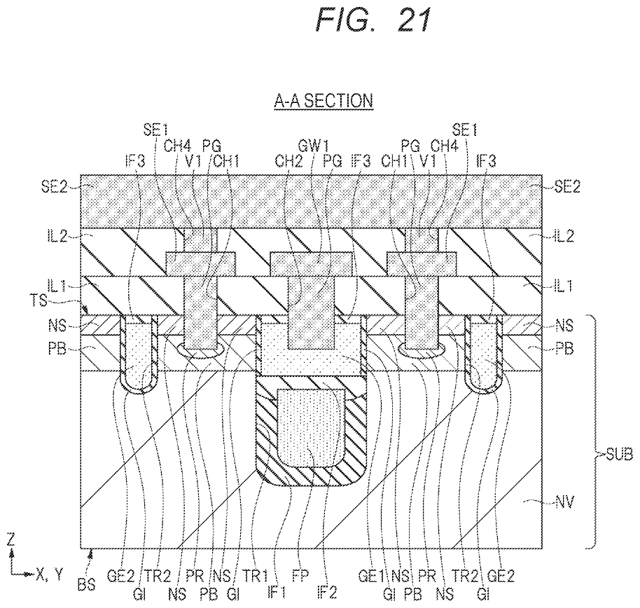

As shown in FIG. 21, an interlayer insulating film IL2, a hole CH4, a via V1, and a source electrode SE2 are formed.

First, an interlayer insulating film IL2 is formed on the interlayer insulating film IL1 by, for example, a CVD method so as to cover the inner wiring SE1 and the inner wiring GW1. Next, a resist pattern having a pattern for opening the inner wiring SE1 is formed on the interlayer insulating film IL2. Next, an anisotropic etch process is performed using the resist pattern as a mask to form a hole CH4 reaching the inner wiring SE1 in the interlayer insulating film IL2. Through these steps, a hole CH4 reaching the inner wiring GW1 is also formed in the interlayer insulating film IL2 in the outer peripheral region OR.

Next, a third barrier metal film is formed inside the hole CH4 and on the interlayer insulating film IL2 by a sputtering method or a CVD method. The third barrier metal film is formed of, for example, a laminated film of a titanium nitride film and a titanium film. Next, a third conductive film is formed on the third barrier metal film by CVD method. The third conductive film is made of, for example, a tungsten film. Next, the third barrier metal film and the third conductive film formed outside the hole CH4 are removed by a CMP method or an anisotropic etch process. As a result, a via V1 including the third barrier metal film and the third conductive film is formed so as to fill the inside of the hole CH4.

Next, a fourth barrier metal film is formed on the interlayer insulating film IL2 by sputtering. The fourth barrier metal film is formed of, for example, a titanium tungsten film. Next, a fourth conductive film is formed on the fourth barrier metal film by sputtering. The fourth conductive film is, for example, an aluminum alloy film to which copper or silicon is added. Next, the fourth barrier metal film and the fourth conductive film are patterned to form the source electrode SE2. Through these steps, the gate wiring GW2 is formed on the interlayer insulating film IL2 in the outer peripheral region OR.

Next, although not illustrated here, a protective film made of, for example, a polyimide film is formed on the source electrode SE2 and on the gate wiring GW2 by, for example, a coating method. By forming an opening in a part of the protective film, regions of the source electrode SE2 and the gate wiring GW2 that become the source pad SP and the gate pad GP are exposed.

Thereafter, the structure shown in FIG. 5 is obtained through the following manufacturing process. First, the bottom BS of the semiconductor substrate SUB is polished as needed. Next, an n-type drain-region ND is formed by introducing, for example, arsenic (As) or the like into the lower surface BS of the semiconductor substrate SUB by ion-implantation. When the semiconductor substrate SUB is composed of a stack of an n-type silicon substrate and an n-type semiconductor layer, the high-concentration n-type silicon substrate forms a drain region ND, and thus forming of the drain region ND by the ion-implantation described above can be omitted. Next, a drain electrode DE is formed below the lower surface BS of the semiconductor substrate SUB by a sputtering method.

The planar layouts of the source electrode SE2, the gate wiring GW2, the inner wiring SE1, and the inner wiring GW1 shown in FIGS. 1 and 2 are merely exemplary and can be variously changed as long as the gate electrode GE1, the gate electrode GE2, the source area NS, and the like are electrically connected.

### First Modified Example

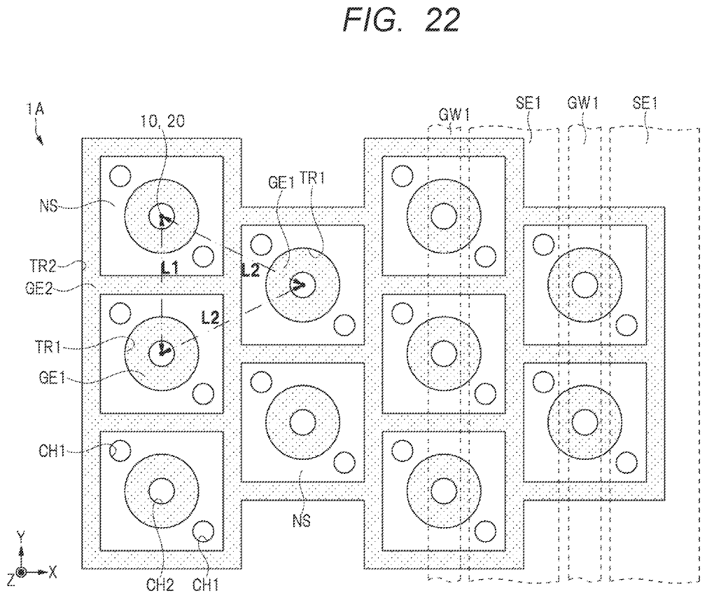

A semiconductor device 100 in first modified example of the first embodiment will be described below with reference to FIG. 22.

In the first embodiment, a honeycomb structure is applied to the planar shape of the trench TR2, but the shape in which the trench TR2 surrounds the trench TR1 is not limited to a regular hexagonal shape and may be another polygonal shape.

In first modified example, for example, as shown in FIG. 22, the trench TR2 is structured such that a plurality of regular squares are connected to each other. In FIG. 22, a regular square adjacent to a certain regular square in the X direction is arranged at a half pitch offset in the Y direction. Even in the first modified example, the center portion 10 of the trench TR1 in plan view coincides with the center of gravity 20 of the regular square (the center of gravity of the polygon). When the center portions 10 of the three nearest trenches TR1 are connected by a straight line, an isosceles triangle is formed, and the length L2 differs from the length L1.

Even when the trench TR2 is shaped like the first modified example, it is possible to stabilize the charge balance in which the on-resistance is reduced and the breakdown voltage is secured. However, the equilateral triangle is superior to the isosceles triangle from the viewpoint that the depletion layer extending from the field plate electrode FP easily spreads evenly in the cell area CR. Therefore, the first embodiment is superior to first modified example in terms of securing the withstand voltage and further stabilizing the charge balance.

### Second Embodiment

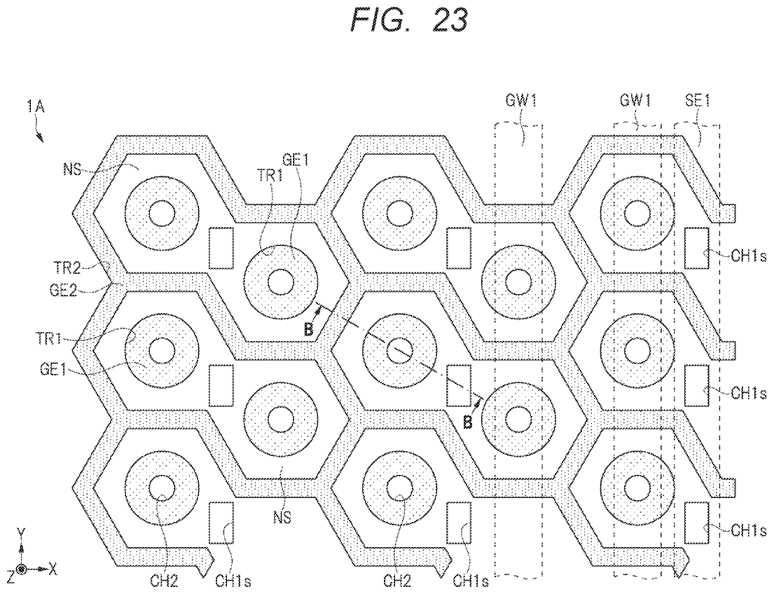

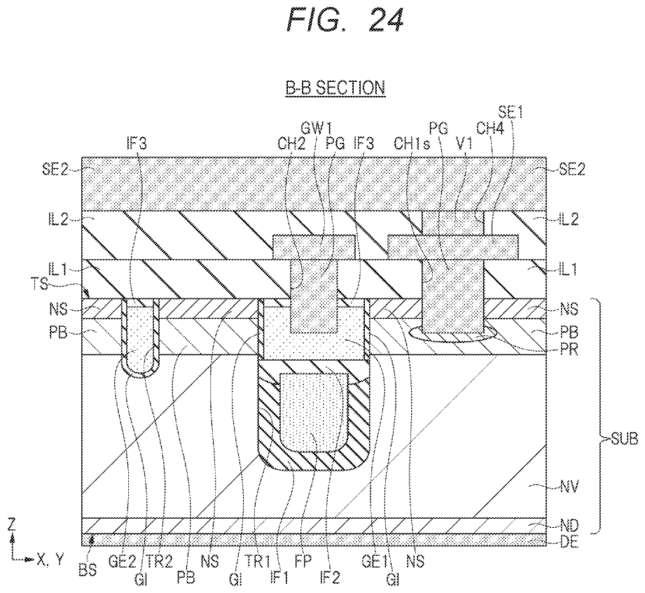

The semiconductor device 100 in the second embodiment will be described below with reference to FIG. 23 and FIG. 24. Note that, in the following description, differences from the first embodiment will be mainly described, and the description of overlapping points with the first embodiment will be omitted. FIG. 24 is a cross-sectional view along line B-B shown in FIG. 23.

In the first embodiment, one trench TR1 was formed in one regular hexagon of the honeycomb structure of the trench TR2.

As shown in FIG. 23, in the second embodiment, the sides shared by the regular hexagons adjacent to each other in the honeycomb structure are omitted. Here, the sides shared by two regular hexagons of the honeycomb structure are omitted, and the two trench TR1 are surrounded by the trench TR2 in plan view.

As shown in FIGS. 23 and 24, a hole CH1s is formed in an area where shared sides are omitted. Since there is no trench TR2 located between the two trench TR1, the planar dimension of the hole CH1s can be made larger than the hole CH1 of the first embodiment. Therefore, the contact area between the plug PG formed in the hole CH1s and the source region NS, the body region PB, and the high-concentration diffusion region PR can be increased, and the contact resistance can be reduced. In addition, in MOSFET of two split-gate structures, the hole CH1s can be shared.

For example, in the first embodiment, two holes CH1 are provided in one regular hexagon of the honeycomb structure. However, regarding the planar dimensions and locations of the holes CH1, it was necessary to consider the spacing between the trench TR1 and the trench TR2, and a certain degree of limitation has been provided. By taking advantage of regions where the shared sides are omitted as the second embodiment, it is possible to alleviate limitations on the planar dimensions and location of the hole CH1s.

However, in the second embodiment, since the shared side is omitted, the density of the gate electrode GE2 is less and the on-resistance is increased as compared with the first embodiment. Therefore, the first embodiment is superior to the second embodiment in terms of reducing the on-resistance.

### Second Modified Example

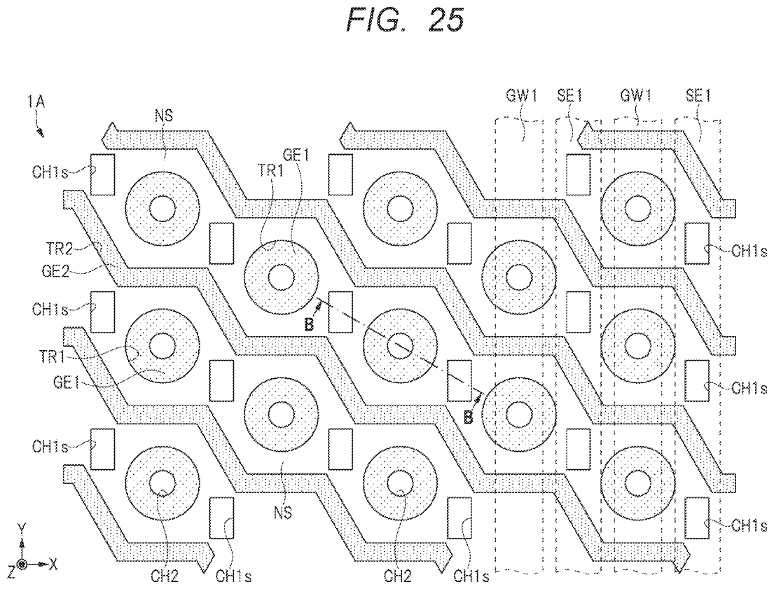

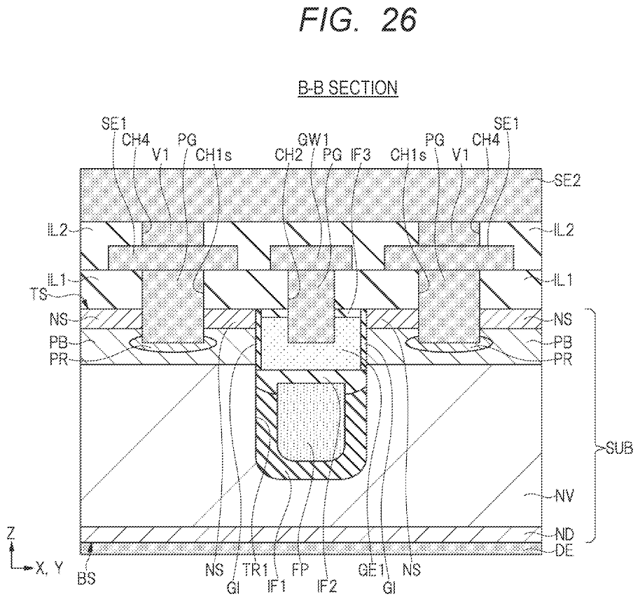

Hereinafter, a semiconductor device 100 in the second modified example of the second embodiment will be described with reference to FIG. 25 and FIG. 26. FIG. 26 is a cross-sectional view along line B-B shown in FIG. 25.

As shown in FIG. 25, in the second modified example as well as in the second embodiment, sides of the honeycomb-structure that are shared by adjacent regular hexagons are omitted. In the second modified example, omitting is performed on the sides shared by a plurality of regular hexagons in the honeycomb structure. That is, a plurality of trenches TR1 are surrounded by the trench TR2 in plan view. In FIG. 25, the trench TR2 is divided into a plurality of trenches, but these trenches TR2 are connected to each other, for example, in the vicinity of the outer periphery of the cell region CR.

As shown in FIGS. 25 and 26, a hole CH1s is formed in each of a plurality of regions in which shared sides are omitted. That is, each hole CH1s is provided between each of the plurality of trenches TR1. Therefore, the number of the plurality of holes CH1s surrounded by the trench TR2 in plan view is smaller by one than the number of the plurality of trenches TR1 surrounded by the trench TR2 in plan view.

In the case of second modified example, since the shared side is omitted, the arrangement density of the gate electrode GE2 is lower than that of the first embodiment, and the on-resistance is increased. However, if the variation of the on-resistance can be tolerated, the number of omitting for the shared sides can be adjusted to increase the flexibility of layout of the hole CH1s.

### Third Embodiment

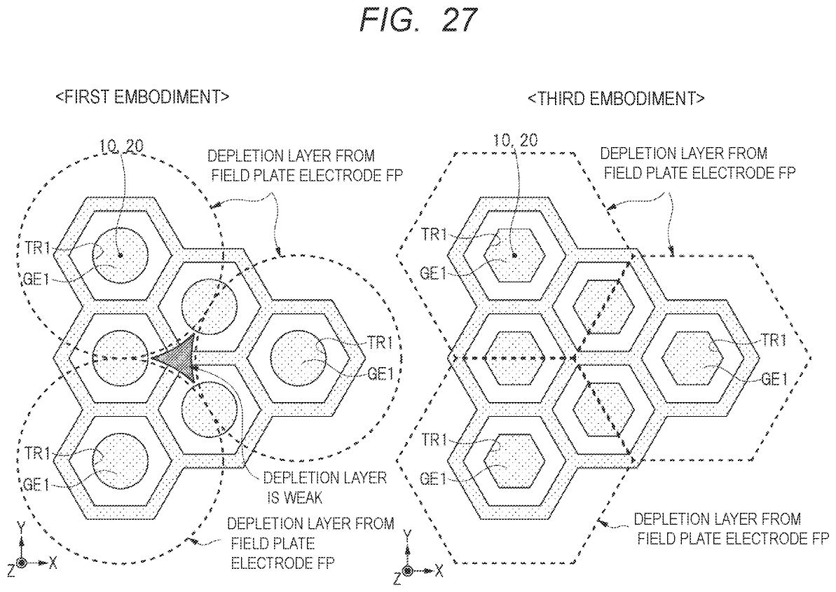

A semiconductor device 100 in the third embodiment will be described below with reference to FIG. 27. Note that, in the following description, differences from the first embodiment will be mainly described, and the description of overlapping points with the first embodiment will be omitted.

In the first embodiment, the trenches TR1 are provided in the trench TR2 so that the planar shape of the trench TR1 is circular and the center portion 10 of the trench TR1 in plan view coincides with the center of gravity 20 of one regular hexagon of the honeycomb structure. As a result, the depletion layer extending from the field plate electrode FP easily spreads evenly in the cell region CR.

However, as shown in FIG. 27, when the trench TR1 has a circular shape, the depletion layer extending from the field plate electrode FP also has a circular shape. Thus, there may be regions with weak depletion, depending on the respective potential and processing dimensions used. For example, there may be regions where the depletion layer does not reach from any of the three field plate electrodes FP. That is, in the cell region CR, there is a region that is not stable locally in charge balance.

As shown in FIG. 27, in the third embodiment, the planar shape of the trench TR1 in the third embodiment is a regular hexagonal shape, although the point at which the center portion 10 of the trench TR1 in plan view coincides with the center of gravity 20 of the regular hexagon is the same as the first embodiment.

By changing the regular hexagonal shape of the trench TR1 as described above, the depletion layer extending from the field plate electrode FP also has a regular hexagonal shape. Therefore, it is possible to suppress generation of a region in which depletion is weak, and thus it is possible to further stabilize charge balancing in the cell region CR.

In addition, the regular hexagonal shape of the trench TR1 is arranged along the regular hexagonal shape of the honeycomb structure so that the trench TR1 is efficiently surrounded by the trench TR2 in the arrangement, considering the interval between the trench TR1 and the trench TR2. That is, each side of the regular hexagon of the trench TR1 is along each side of the regular hexagon of the trench TR2.

Also, in the third embodiment, as in the second embodiment or second modified example, the sides shared by the adjacent regular hexagons of the honeycomb structure may be thinned out.

### Fourth Embodiment

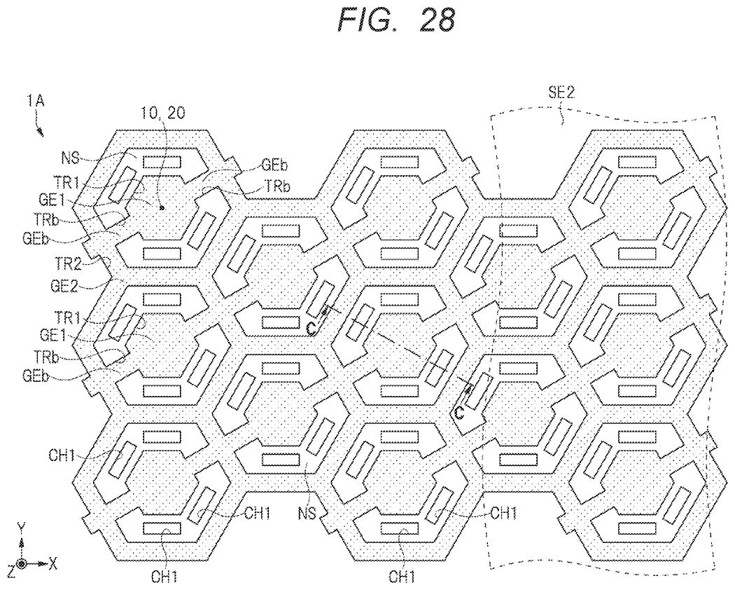

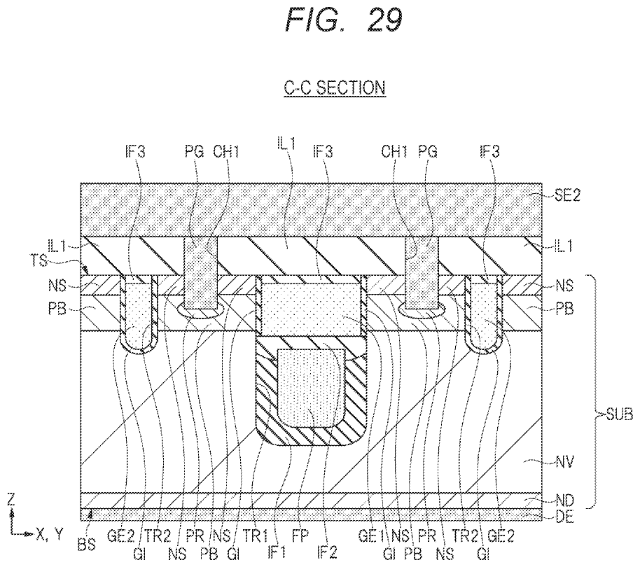

The semiconductor device 100 in fourth embodiment will be described below with reference to FIG. 28 and FIG. 29. Note that, in the following description, differences from the first embodiment will be mainly described, and the description of overlapping points with the first embodiment will be omitted. FIG. 29 is a cross-sectional view along C-C shown in FIG. 28.

Note that in fourth embodiment, a case where the planar shape of the trench TR1 is a hexagonal shape as in the third embodiment is exemplified, but the effect of the fourth embodiment can be achieved even if the planar shape of the trench TR1 is a circular shape.

In the first embodiment, the trench TR1 and the trench TR2 are separated from each other in the cell region CR, and the gate electrode GE1 and the gate electrode GE2 are separated from each other. Then, in the cell region CR, the gate electrode GE1 is connected to the inner wiring GW1, and in the outer peripheral region OR, the gate electrode GE2 is connected to the inner wiring GW1, so that the gate potential is supplied to the gate electrode GE1 and the gate electrode GE2.

As shown in FIG. 28, in the fourth embodiment, in the cell region CR, a communication portion TRb that reaches a predetermined depth from the upper surface TS of the semiconductor substrate SUB and communicates with the trench TR1 and the trench TR2 is formed in the semiconductor substrate SUB. A connection portion GEb integrated with the gate electrode GE1 and the gate electrode GE2 is formed inside the communication portion TRb.

Such a communication portion TRb can be formed by not disposing the hard mask HM on the upper surface TS of the semiconductor substrate SUB located between the trench TR1 and the trench TR2 in the manufacturing process of FIG. 8. That is, the depth of the communication portion TRb is the same as the depth of the trench TR2. Further, in the step of forming the gate electrode GE1 and the gate electrode GE2 from the conductive film CF1, the connection portion GEb can also be formed.

In the fourth embodiment, since the gate electrode GE1 and the gate electrode GE2 are integrated, there is no need to connect the gate electrode GE1 to the inner wiring GW1 via the hole CH1. Therefore, there is no need to provide an internal wiring GW1, and there is no need to provide an internal wiring SE1, an interlayer insulating film IL2, a hole CH4, and a via V1.

As shown in FIG. 29, in the fourth embodiment, the inner wiring GW1, the inner wiring SE1, the interlayer insulating film IL2, the hole CH4, and the via V1 are not formed, and the source electrode SE2 and the gate wiring GW2 are formed on the interlayer insulating film IL1. A hole CH1 is formed in the interlayer insulating film IL1, and a plug PG is formed inside the hole CH1. The source region NS, the body region PB, and the high concentration diffusion region PR are electrically connected to the source electrode SE2 via hole CH1 (plug PG).

As shown in FIG. 6, in the fourth embodiment as well, an lead-out trench TRa is formed in the semiconductor substrate SUB of the outer peripheral region OR. The trench TR2 and the lead-out trench TRa are in communication. A lead-out portion GEa integrated with the gate electrode GE2 is formed inside the lead-out trench TRa.

A hole CH3 reaching the lead-out portion GEa is formed in the interlayer insulating film IL1 of the outer peripheral region OR. A plug PG is also formed inside the hole CH3. The lead-out portion GEa is electrically connected to the gate wiring GW2 via hole CH3 (plug PG). Therefore, the gate potential is supplied from the gate wiring GW2 to the gate electrode GE2, the connection portion GEb, and the gate electrode GE1.

As described above, according to the fourth embodiment, by providing the communication portion TRb, it is possible to simplify the structure of a semiconductor device 100 and simplify the manufacturing process.

In addition, the communication portion TRb (connection portion GEb) can also be used as a single-gate structure MOSFET because the source-region NS is formed in the semiconductor substrate on both side surfaces of the communication portion TRb (connection portion GEb). Therefore, the on-resistance can be further reduced.

Also, in the fourth embodiment, as in the second embodiment or the second modified example, the sides shared by the adjacent regular hexagons of the honeycomb structure may be omitted.

### Fifth Embodiment

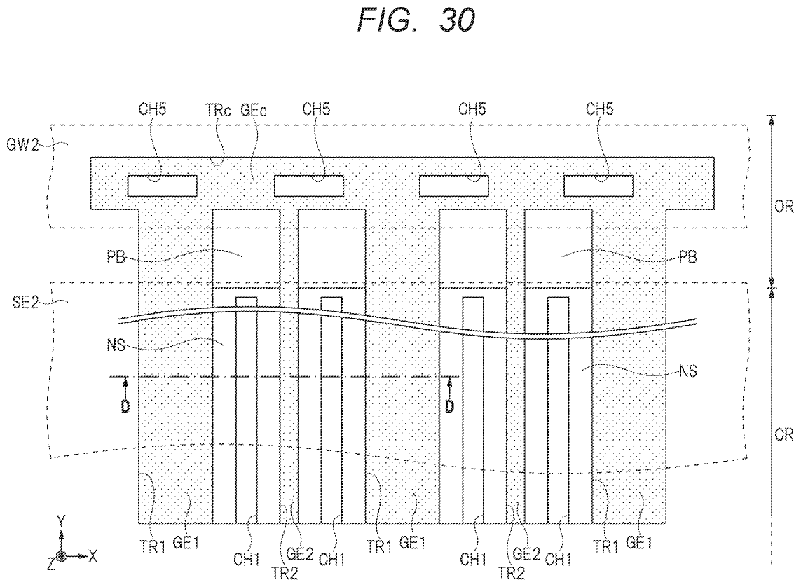

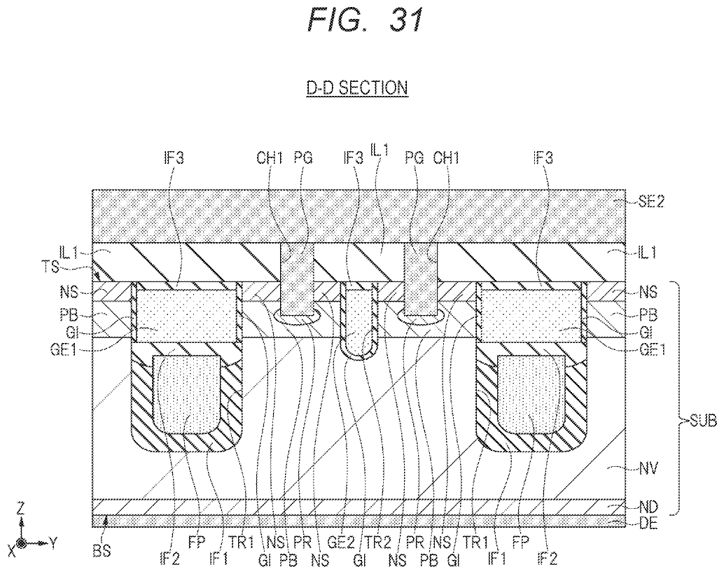

A semiconductor device 100 in the fifth embodiment will be described below with reference to FIG. 30 and FIG. 31. Note that, in the following description, differences from the first embodiment will be mainly described, and the description of overlapping points with the first embodiment will be omitted. FIG. 30 shows a planar pattern of the trench TR1, TR2 and the gate electrode GE1, GE2 formed in the semiconductor substrate SUB mainly in the cell region CR and the outer peripheral region OR. FIG. 31 is a cross-sectional view along D-D shown in FIG. 30.

In the first embodiment, the trench TR2 has a honeycomb structure in plan view, and the trench TR1 is surrounded by the trench TR2 in plan view.

As shown in FIG. 30, in the fifth embodiment, the trench TR1 and the trench TR2 are formed in a stripe-like shape. That is, as shown in FIG. 30, the trench TR1 and the trench TR2 extend in the Y direction, respectively, and adjoin each other in the X direction intersecting the Y direction. As shown in FIGS. 30 and 31, the hole CH1 reaching the source-region NS extends in the Y-direction and is located between the trench TR1 and the trench TR2 in the X-direction.

In the outer peripheral region OR, an lead-out trench TRc that reaches a predetermined depth from the upper surface TS of the semiconductor substrate SUB and communicates with the trench TR1 and the trench TR2 is formed in the semiconductor substrate SUB. A lead-out portion GEc integrated with the gate electrode GE1 and the gate electrode GE2 is formed inside the lead-out trench TRc. That is, the lead-out portion GEc is formed of the conductive film CF1 in the same manner as the gate electrode GE1 and the gate electrode GE2.

Since the gate electrode GE1 and the gate electrode GE2 are integrated, there is no need to connect the gate electrode GE1 to the inner wiring GW1 via the hole CH1. Therefore, as shown in FIG. 31, the inner wiring GW1, the inner wiring SE1, the interlayer insulating film IL2, the hole CH4, and the via V1 are not formed, and the source electrode SE2 and the gate wiring GW2 are formed on the interlayer insulating film IL1. A hole CH1 is formed in the interlayer insulating film IL1, and a plug PG is formed inside the hole CH1. The source region NS, the body region PB, and the high concentration diffusion region PR are electrically connected to the source electrode SE2 via hole CH1 (plug PG).

A hole CH5 reaching the lead-out portion GEc is formed in the interlayer insulating film IL1 of the outer peripheral region OR. A plug PG is formed inside the hole CH5. The lead-out portion GEc is electrically connected to the gate wiring GW2 via hole CH5 (plug PG). Therefore, the gate potential is supplied from the gate wiring GW2 to the lead-out portion GEc, the gate electrode GE1, and the gate electrode GE2.

The field plate electrode FP of the fifth embodiment may be electrically floating, similar to the first embodiment, but may be electrically connected to the source electrode SE2. Then, a source potential is supplied from the source electrode SE2 to the field plate electrode FP.

Although not illustrated here, when the source electrode SE2 and the field plate electrode FP are electrically connected to each other, a portion of the field plate electrode FP below the source electrode SE2 is formed not only in the lower portion of the trench TR1 but also in the upper portion of the trench TR1 as a lead-out portion. That is, in the trench TR1, there is a portion where only the field plate electrode FP is formed in addition to a portion where both the field plate electrode FP and the gate electrode GE1 are formed.

A hole is formed in the interlayer insulating film IL1 to reach a lead-out portion of the field plate electrode FP. A plug PG is formed inside the hole. The lead-out portion of the field plate electrode FP is electrically connected to the source electrode SE2 via the hole (plug PG).

According to the fifth embodiment, since there is no need to form the inner wiring GW1, the inner wiring SE1, and the like as compared with the first embodiment, it is possible to simplify the construction of a semiconductor device 100 and simplify the manufacturing process.

In addition, since the trench TR1 has a stripe-like shape, the depletion layer extending from the field plate electrode FP easily spreads evenly in the cell region CR. It is possible to stabilize the charge balance of achieving both reducing of the on-resistance and securing of the breakdown voltage. However, in the fifth embodiment, the density of the gate electrode GE2 is less and the on-resistance is increased compared to the first embodiment. Therefore, the honeycomb structure of the first embodiment is superior to the stripe-like structure of the fifth embodiment in terms of reduction in on-resistance.

### Third Modified Example

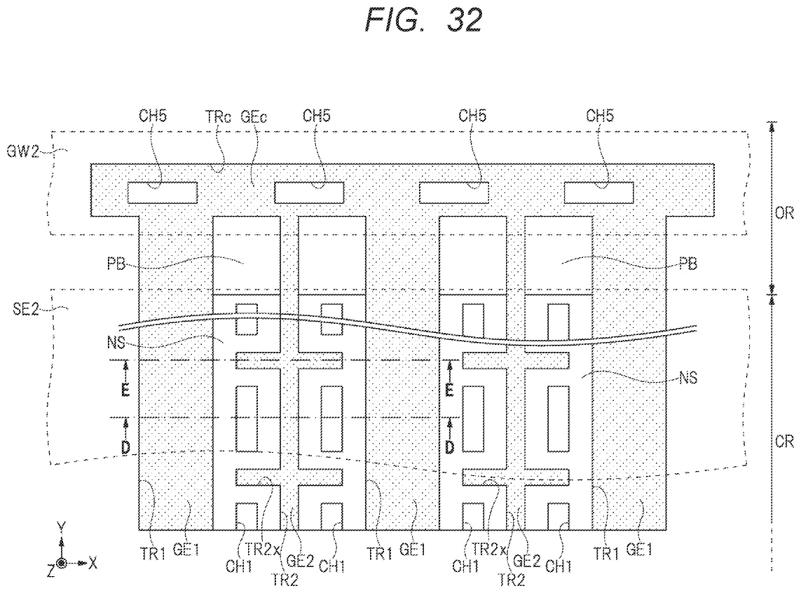

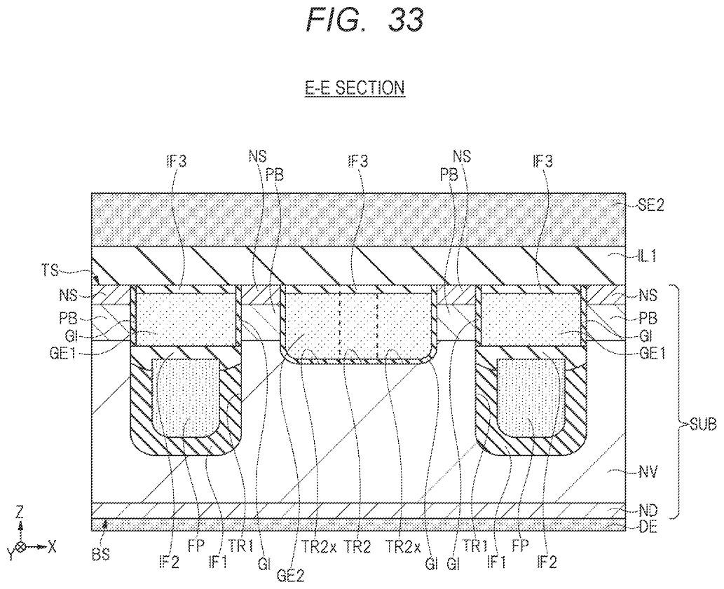

Hereinafter, a semiconductor device 100 in the third modified example of the fifth embodiment will be described with reference to FIG. 32 and FIG. 33. FIG. 33 is a cross-sectional view along E-E shown in FIG. 32.

As shown in FIGS. 32 and 33, in the third modified example, a portion of the trench TR2 is provided with an intersection portion TR2x extending in the X-direction. The gate electrode GE2 is also formed inside the intersection portion TR2x. The trench TR2 may be provided with a plurality of intersection portions TR2x. In addition, the hole CH1 is divided into a plurality of portions and arranged in the Y-direction so as not to overlap with the intersecting portion TR2x in plan view.

In the third modified example, since the intersection TR2x is provided, the density of the gate electrode GE2 is higher and the on-resistance can be reduced as compared with the fifth embodiment.

Although the present invention has been described in detail based on the above-described embodiments, the present invention is not limited to the above-described embodiments and can be variously modified without departing from the gist thereof.

What is claimed is:

1. A semiconductor device comprising:
a semiconductor substrate of a first conductivity type having an upper surface and a lower surface;
a first trench formed in the semiconductor substrate so as to reach a predetermined depth from the upper surface of the semiconductor substrate;
a field plate electrode formed in a lower portion of the first trench inside the first trench and electrically isolated from the semiconductor substrate;
a first gate electrode formed in an upper portion of the first trench inside the first trench and electrically isolated from the semiconductor substrate and the field plate electrode;
a second trench formed in the semiconductor substrate so as to reach a predetermined depth from the upper surface of the semiconductor substrate; and
a second gate electrode formed inside the second trench and electrically isolated from the semiconductor substrate,
wherein a depth of the first trench is greater than a depth of the second trench; and
wherein the first trench is surrounded by the second trench in plan view.

2. The semiconductor device according to claim 1, wherein a gate potential is supplied to the first gate electrode and the second gate electrode, and the field plate electrode is electrically floating.

3. The semiconductor device according to claim 1, wherein the second trench forms a honeycomb structure in plan view, and one first trench is formed in a regular hexagon of the honeycomb structure.

4. The semiconductor device according to claim 1, wherein the second trench forms a honeycomb structure in plan view, and a center portion of the first trench in plan view corresponds to a center of gravity of a regular hexagon of the honeycomb structure.

5. The semiconductor device according to claim 4, wherein the first trench has a circular planar shape.

6. The semiconductor device according to claim 4, wherein the planar shape of the first trench is a regular hexagonal shape, and each side of the regular hexagon of the first trench is along each side of the regular hexagon of the second trench.

7. The semiconductor device according to claim 1, further comprising:
a body region of a second conductivity type opposite to the first conductivity type formed in the semiconductor substrate so that a depth from the upper surface of the semiconductor substrate is shallower than a depth of each of the first trench and the second trench;
a source region of the first conductivity type formed in the body region;
a lead-out trench formed in the semiconductor substrate so as to reach a predetermined depth from the upper surface of the semiconductor substrate, the lead-out trench being integrated with the second trench;
a lead-out portion formed inside the lead-out trench, electrically isolated from the semiconductor substrate, and integrated with the second gate electrode;
a first interlayer insulating film formed on the upper surface of the semiconductor substrate;
a first hole, a second hole, and a third hole formed in the first interlayer insulating film;
a first wiring and a second wiring formed on the first interlayer insulating film;
a second interlayer insulating film formed on the first interlayer insulating film so as to cover the first wiring and the second wiring;
a fourth hole and a fifth hole formed in the second interlayer insulating film; and
a source electrode and a gate wiring formed on the second interlayer insulating film,
wherein the first hole reaches the source region and the body region,
wherein the second hole reaches the first gate electrode;
wherein the third hole reaches the lead-out portion;
wherein the first wiring is electrically connected to the source region and the body region via the first hole;
wherein the second wiring is electrically connected to the first gate electrode via the second hole and is electrically connected to the lead-out portion via the third hole;
wherein the fourth hole reaches the first wiring;
wherein the fifth hole reaches the second wiring;
wherein the source electrode is electrically connected to the first wiring via the fourth hole; and
wherein the gate wiring is electrically connected to the second wiring via the fifth hole.

8. The semiconductor device according to claim 1,
wherein a plurality of the first trenches is formed in the semiconductor substrate;
wherein the field plate electrode and the first gate electrode are formed inside the plurality of the first trenches, respectively; and
wherein the plurality of the first trenches is surrounded by the second trench in plan view.

9. The semiconductor device according to claim 8, wherein the second trench has a honeycomb structure in plan view, and sides of the honeycomb structure shared by adjacent regular hexagons are removed.

10. The semiconductor device according to claim 9, further comprising:
a body region of a second conductivity type opposite to the first conductivity type formed in the semiconductor substrate so that a depth from the upper surface of the semiconductor substrate is shallower than a depth of each of the first trench and the second trench;
a source region of the first conductivity type formed in the body region;
a lead-out trench formed in the semiconductor substrate so as to reach a predetermined depth from the upper surface of the semiconductor substrate, the lead-out trench being integrated with the second trench;
a lead-out portion formed inside the lead-out trench, electrically isolated from the semiconductor substrate, and integrated with the second gate electrode;
a first interlayer insulating film formed on the upper surface of the semiconductor substrate;
a plurality of first holes, a second hole, and a third hole formed in the first interlayer insulating film;
a first wiring and a second wiring formed on the first interlayer insulating film;
a second interlayer insulating film formed on the first interlayer insulating film so as to cover the first wiring and the second wiring;
a fourth hole and a fifth hole formed in the second interlayer insulating film; and
a source electrode and a gate wiring formed on the second interlayer insulating film,
wherein each of the plurality of first holes reaches the source region and the body region, and provided between the plurality of first trenches in plan view;
wherein the second hole reaches the first gate electrode;
wherein the third hole reaches the lead-out portion;
wherein the first wiring is electrically connected to the source region and the body region via the plurality of first holes;
wherein the second wiring is electrically connected to the first gate electrode via the second hole and is electrically connected to the lead-out portion via the third hole;
wherein the fourth hole reaches the first wiring;
wherein the fifth hole reaches the second wiring;
wherein the source electrode is electrically connected to the first wiring via the fourth hole; and
wherein the gate wiring is electrically connected to the second wiring via the fifth hole.

11. The semiconductor device according to claim 10, wherein the number of the plurality of first holes surrounded by the second trench in plan view is one fewer than the number of the plurality of first trenches surrounded by the second trench in plan view.

12. The semiconductor device according to claim 1,
wherein the semiconductor substrate has a communication portion that reaches a predetermined depth from the upper surface of the semiconductor substrate and communicates with the first trench and the second trench, and
wherein a connection portion that is integrated with the first gate electrode and the second gate electrode is formed inside the communication portion.

13. The semiconductor device according to claim 12 further comprising:
a body region of a second conductivity type opposite to the first conductivity type formed in the semiconductor substrate so that a depth from the upper surface of the semiconductor substrate is shallower than a depth of each of the first trench and the second trench;
a source region of the first conductivity type formed in the body region;
a lead-out trench formed in the semiconductor substrate so as to reach a predetermined depth from the upper surface of the semiconductor substrate, the lead-out trench being integrated with the second trench;
a lead-out portion formed inside the lead-out trench, electrically isolated from the semiconductor substrate, and integrated with the second gate electrode;
a first interlayer insulating film formed on the upper surface of the semiconductor substrate;
a first hole and a second hole formed in the first interlayer insulating film; and
a source electrode and a gate wiring formed on the first interlayer insulating film,
wherein the first hole reaches the source region and the body region;
wherein the second hole reaches the lead-out portion;
wherein the source electrode is electrically connected to the source region and the body region via the first hole;
wherein the gate wiring is electrically connected to the lead-out portion via the second hole.

14. A semiconductor device comprising:
a semiconductor substrate of a first conductivity type having an upper surface and a lower surface;
a first trench formed in the semiconductor substrate so as to reach a predetermined depth from the upper surface of the semiconductor substrate;
a field plate electrode formed in a lower portion of the first trench inside the first trench and electrically isolated from the semiconductor substrate;
a first gate electrode formed in an upper portion of the first trench inside the first trench and electrically isolated from the semiconductor substrate and the field plate electrode;
a second trench formed in the semiconductor substrate so as to reach a predetermined depth from the upper surface of the semiconductor substrate; and
a second gate electrode formed inside the second trench and electrically isolated from the semiconductor substrate, wherein a depth of the first trench is greater than a depth of the second trench; and
wherein, in plan view, the first trench and the second trench each extend in a first direction and adjoin each other in a second direction intersecting the first direction.

15. The semiconductor device according to claim 14, wherein a gate potential is supplied to the first gate electrode and the second gate electrode, and a source potential is supplied to the field plate electrode.

16. The semiconductor device according to claim 14, wherein a portion of the second trench is provided with an intersection extending in the second direction, and the second gate-electrode is also formed inside the intersection.

17. The semiconductor device according to claim 14, further comprising:
a body region of a second conductivity type opposite to the first conductivity type formed in the semiconductor substrate so that a depth from the upper surface of the semiconductor substrate is shallower than a depth of each of the first trench and the second trench;
a source region of the first conductivity type formed in the body region;
a first interlayer insulating film formed on the upper surface of the semiconductor substrate;
a first hole and a second hole formed in the first interlayer insulating film; and
a source electrode and a gate wiring formed on the first interlayer insulating film,
wherein a lead-out trench which reaches a predetermined depth from the upper surface of the semiconductor substrate, and which is integrated with the first trench and the second trench, is formed in the semiconductor substrate;
wherein a lead-out portion electrically isolated from the semiconductor substrate and integrated with the first gate electrode and the second gate electrode is formed inside the lead-out trench;
wherein the first hole reaches the source region and the body region;
wherein the second hole reaches the lead-out portion;
wherein the source electrode is electrically connected to the source region and the body region via the first hole; and
wherein the gate wiring is electrically connected to the lead-out portion via the second hole.
